(19) United States
(12) Patent Application Publication
(10) Pub. No.: US 2015/0027518 A1
(43) Pub. Date: Jan. 29, 2015

(54) WIDE ANGLE THREE-DIMENSIONAL SOLAR CELLS

(71) Applicant: Solar3D, Inc., Santa Barbara, CA (US)

(72) Inventors: Mehmet Nadir Dagli, Goleta, CA (US); Changwan Son, Isla Vista, CA (US)

(21) Appl. No.: 14/380,355

(22) PCT Filed: Feb. 20, 2013
(86) PCT No.: PCT/US2013/026914

§ 371 Date: Aug. 21, 2014

Related U.S. Application Data
(60) Provisional application No. 61/601,796, filed on Feb. 22, 2012.
(60) Provisional application No. 61/671,612, filed on Jul. 13, 2012.

(51) Int. Cl. H01L 31/0236; H01L 31/0687; H01L 31/0232

(52) U.S. Cl. CPC H01L 31/02363; H01L 31/02327; H01L 31/0687
USPC 136/255

(57) ABSTRACT

A three dimensional solar cell composed of a semiconductor body that has a substantially flat bottom surface, and shaped trenches formed in an arrayed manner along its top side. Thus, multiple pillars are thereby formed in the semiconductor body extending toward the top side of the semiconductor body. A light collecting material fills the shaped trenches along the top side of the semiconductor body and forms a substantially flat light receiving top surface parallel to the bottom surface of the semiconductor body. Each of at least some of the trenches are structured such that there exists at least one point on the substantially flat light receiving surface that if a light ray is incident on that point, the light ray, if remaining within the corresponding trench, as opposed to entering the semiconductor body, will be redirected upwards at least after a fourth reflection on neighboring pillars.

### BACKGROUND

Solar energy may be harvested by a solar cell as a renewable way to create electricity. The solar cell channels received photons generated in the sun in the form of a light ray (also called a “solar ray”). Ideally, the photon is directed into a semiconductor body that contains a photovoltaic junction. Some of the photons that enter into the depletion zone of the photovoltaic junction will be absorbed therein, and the resulting energy imparted by the absorption will result in an electron-hole pair. An electromagnetic field causes the electrons to be swept towards one electrode, and holes to be swept to the opposite electrode. When the solar cell is exposed to the sun, a regular influx of solar power causes a corresponding generation of electrical power with some efficiency.

There are a variety of ways that a solar photon approaching a solar cell might not be converted into electricity, thereby reducing its potential electrical power generation. The first way is reflection off of the surface of the solar cell back into the environment. For instance, a solar cell is often said to be able to receive solar cells that are incident on the solar cell within a certain range of angles. The wider that angle, the better the solar cell is at receiving solar power throughout the day, given that the suns position changes throughout the day and year.

Another way that efficiency may be reduced is if the solar photon fails to enter the semiconductor body, or is otherwise absorbed in a manner not to be converted into an electron-hole pair. Even if the photon causes an electromagnetic pair, if the pair was not generated in a depletion region, the pair may quickly recombine. Furthermore, power may still be reduced if there is considerable net resistance between the location that the electron-hole pair was generated in the depletion region, and the electrodes that are coupled to the semiconductor body.

Thus, solar cell technology presents a number of challenges to be solved. However, the advancement of solar cell technology has the potential to significantly improve the environment for current and future generations as it represents a clean way to provide for human power appetites and needs.

### BRIEF SUMMARY

At least one embodiment described herein relates to a three dimensional solar cell composed of a semiconductor body. The semiconductor body has a substantially flat bottom surface, and shaped trenches formed in an arrayed manner along the top side of the semiconductor body. Thus, multiple pillars are thereby formed in the semiconductor body extending toward the top side of the semiconductor body. A light collecting material fills the shaped trenches along the top side of the semiconductor body and forms a substantially flat light receiving top surface parallel to the bottom surface of the semiconductor body. Each of at least some of the trenches are structured such that there exists at least one point on the substantially flat light receiving surface that if a light ray is incident on that point, the light ray, if remaining within the corresponding trench, as opposed to entering the semiconductor body, will be redirected upwards at least after a fourth reflection on neighboring pillars.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

In order to describe the manner in which the above-recited and other advantages and features can be obtained, a more particular description of various embodiments will be rendered by reference to the appended drawings. Understanding that these drawings depict only sample embodiments and are not therefore to be considered to be limiting of the scope of the invention, the embodiments will be described and explained with additional specificity and detail through the use of the accompanying drawings in which:

FIG. 1A shows the cross-section of a first embodiment of a three dimensional solar cell in which several solar ray trajectories are shown;

FIG. 1B shows the cross-section of the first embodiment of a three dimensional solar cell in which several alternative solar ray trajectories are shown;

FIG. 2A shows the cross-section of a second embodiment of a three dimensional solar cell in which several solar ray trajectories are shown;

FIG. 2B shows the cross-section of the second embodiment of a three dimensional solar cell in which several alternative solar ray trajectories are shown;

FIG. 3A shows the cross-section of the second embodiment in which one of the electrodes is positioned towards the top side of the semiconductor body along an upper side wall of each pillar;

FIG. 3B shows the cross-section in which one of the electrodes is positioned on the top surface of the semiconductor body;

FIG. 4 illustrates fabrication steps for an alternate way of making wide angle solar cells;

FIG. 5 illustrates a cell structure that results from encapsulating a side of the solar cell;

FIG. 6 illustrates an alternative cross section for the cells;

FIG. 7A illustrates an alternative cross section for the cells;

FIG. 7B illustrates a microscopic cross sectional view of an actual trench array formed according to the approximate design of FIG. 7A; and

FIG. 7C illustrates a microscopic cross sectional view that represents a further zoomed in view of FIG. 7B, and with some measurements added.

### DETAILED DESCRIPTION

Embodiments described herein include a three dimensional solar cell designs with a wide collection angle. Such a wide collection angle may permit the solar cell to be also very efficient. The solar cell designs described have two aspects; one being optical and the other being electrical. These two aspects contribute to high efficiency. On the optical aspect, high efficiency may be enabled by reducing back reflection and having more complete trapping of the incident radiation over a wide and adjustable angular range. On the electrical aspect, high efficiency may be achieved through efficient collection and extraction of the charge carriers, and by keeping ohmic losses (due to contacts and material) very low. Finally, the designs may be manufactured at relatively low cost. These two aspects of optical and electrical design are described in the following sections.

Solar Design

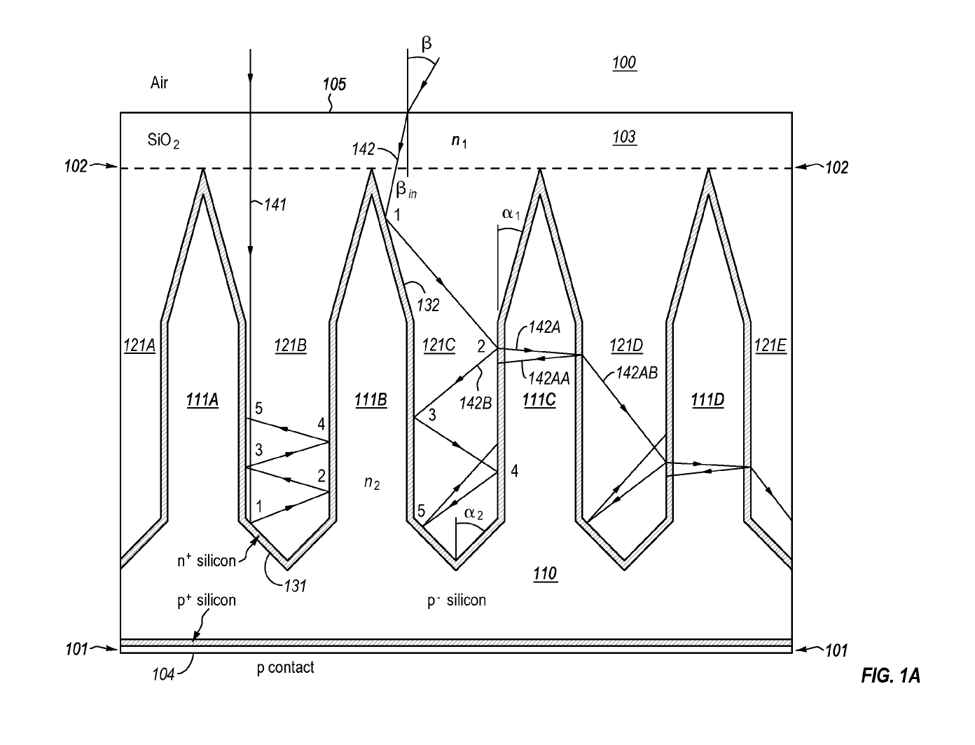

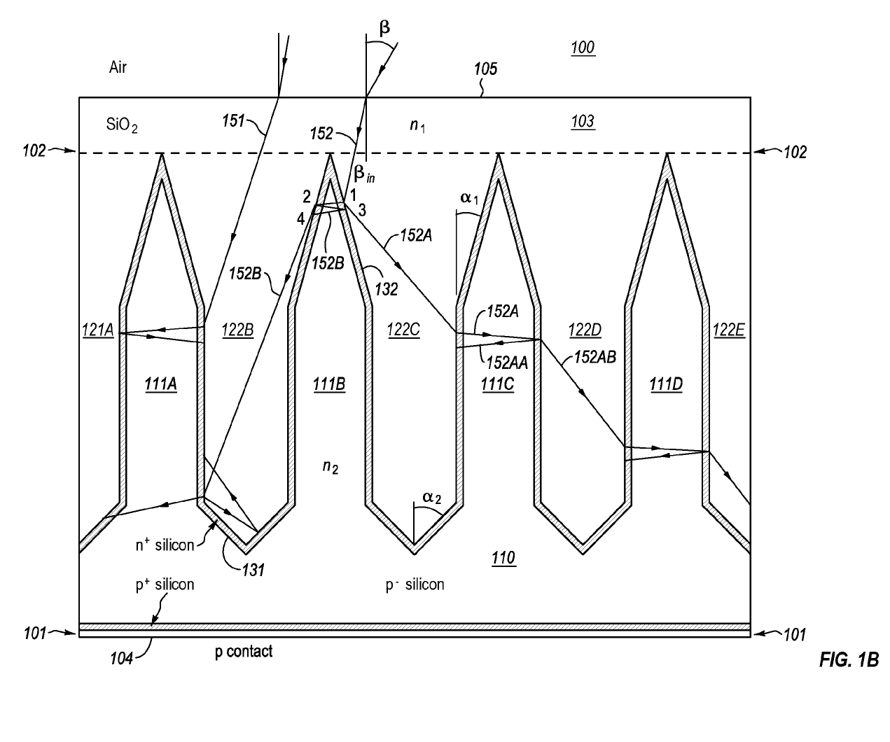

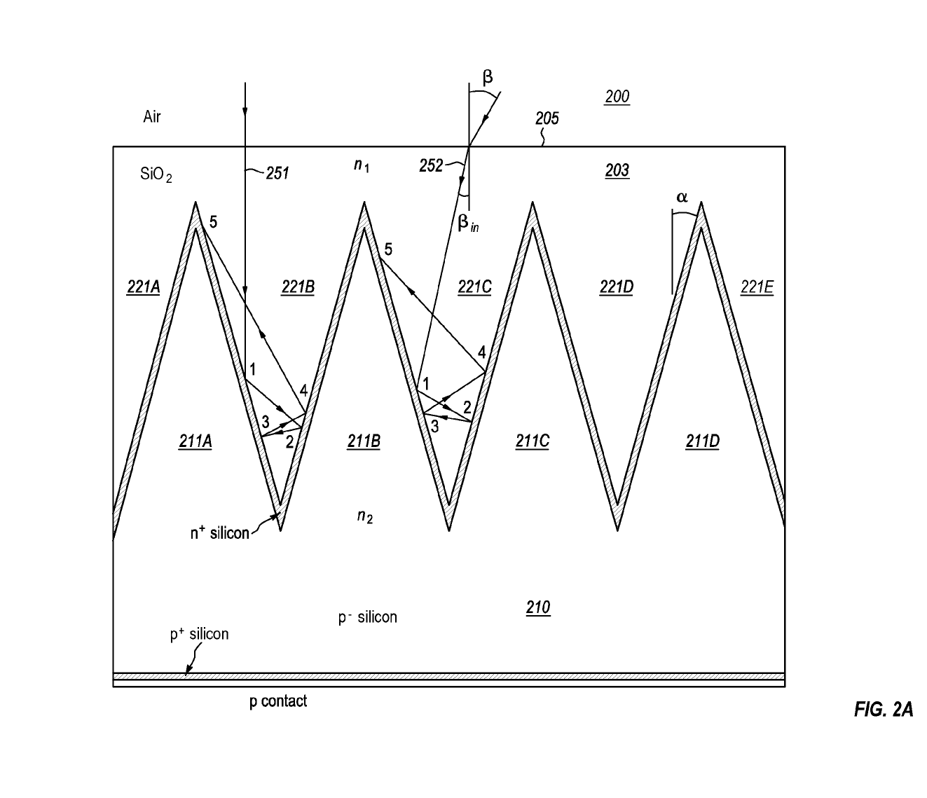

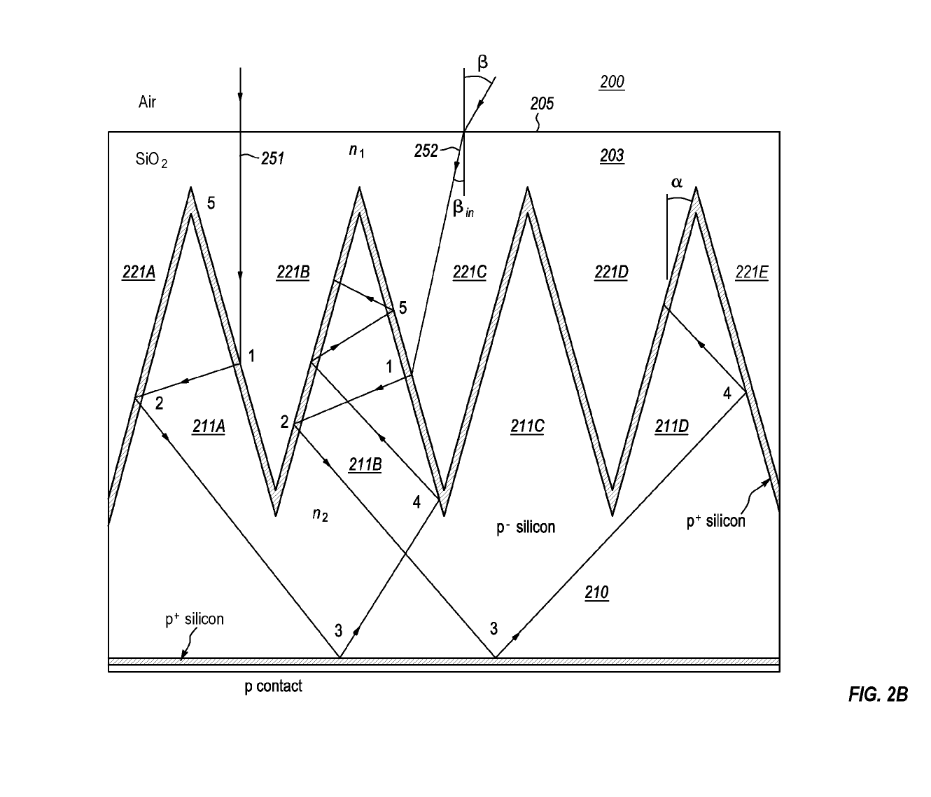

The described solar cell optical designs have advantages in that the solar cell traps the incident solar radiation over a wide angular range of incident light. Thus, more solar radiation is trapped inside the solar cell at a wide range of positions of the sun. In other words, more solar radiation is captured whenever the sun is shining (i.e., yearlong and all day long). This advantage is achieved by shaping the solar cell. Furthermore, while this is possible to achieve using several different shapes, the principles described herein are not limited to any one given design. Nevertheless, for illustrative purposes, one possible design is shown in FIGS. 1A and 1B (collectively referred to as “FIG. 1”), and a second possible design is shown in FIGS. 2A and 2B (collectively referred to as “FIG. 2”).

FIG. 1A shows the cross-section of a three dimensional solar cell 100 in which several solar ray trajectories are shown. FIG. 1B shows the cross section of the three dimensional solar cell 100 in which several alternative solar ray trajectories are shown. In both of the design of FIG. 1, and the design shown further below with respect to FIG. 2, and in accordance with the principles described herein, shaped trenches are etched into silicon. However, any other semiconductor capable of forming a photovoltaic junction will suffice, though silicon is preferred due to its lower cost. These shaped trenches are filled with SiO₂, but any other passivating material such as certain polymers (after a thin surface oxidation) can also be used.

The three dimensional solar cell 100 includes a semiconductor body 110 (as an example formed of silicon) have a substantially flat bottom surface 101. In this description and in the claims the descriptors “bottom” and “top” are merely terms of convention used to distinguish one surface or side from another, though the “top” portion of the solar cell will be positioned to receive sunlight, and thus would most often be positioned upwards to receive sunlight. An electrical contact 104 of one polarity (e.g., a p contact in this case) is coupled along the flat bottom surface 101 of the semiconductor body 110. Positions of the other contact (e.g., the n contact) will be described in subsequent figures.

Shaped trenches 121 (including trenches 121A, 121B, 121C, 121D and 121E) are formed along a top side 102 of the semiconductor body 110 opposite the bottom surface 101. Thus, the semiconductor body 110 forms an array of pillars 111 (including illustrated pillars 111A, 111B, 111C and 111D) between each neighboring shaped trench. In this manner, the semiconductor body 110 has multiple arrayed pillars 111 extending toward the top side 102 of the semiconductor body 110.

A light collecting transparent material 103 (such as SiO₂) fills the arrayed shaped trenches 121 along the top side 102 of the semiconductor body 110. The light collecting material 103 further forms a substantially flat light receiving top surface 105 substantially parallel to the bottom surface 101 of the semiconductor body 110. Each of the arrayed pillars 111 have sidewalls contacting the light collecting transparent material 103.

As can be seen in the cross section of FIGS. 1A and 1B, at least for the horizontal direction along which the cross section is taken, each of the set of pillars has two photovoltaic junctions though a configuration in which there are more such junctions may be possible. Thus, as a light ray travels horizontally through any of the pillars 111, the photons will have two opportunities to be converted in an electron-hole pair in a depletion region. For instance, in FIG. 1, an n+ layer is doped on the surface of the semiconductor body 110. Thus, as a light ray enters the pillar from the side, it will first enter the n+ layer and then encounter the p− silicon bulk that forms the majority of the semiconductor body 110. Accordingly, the light ray would encounter a photovoltaic junction surrounded by a depletion region. As the light ray continues and is about to exit the other side of the pillar, the light ray would exit the p− silicon bulk and enter the n+ layer that coats the other side of the pillar, thus encountering another photovoltaic junction surrounded by a depletion region.

The incoming angular positions of incoming solar rays (also called herein the “collection angle”) change as a function of time. This angular position is represented in FIGS. 1 and 2 by angle β, which is the angle solar rays make with respect to vertical (i.e., perpendicular to the solar cell surface). Solar rays refract at the air/SiO2 interface. Due to Snell's law, the intake angle βᵢₙ at which the solar cell intakes the solar ray is related to the collection angle β according to the following Equation 1:

$${β}_{i n} = {sin}^{- 1} ( \frac{sin β}{{n}_{1}} ) \qquad ( 1 )$$

Therefore, if we call the maximum collection angle βᵢₙₘₐₓ, we obtain the following Equation 2:

$${β}_{i {n}_{m ax}} = {sin}^{- 1} ( \frac{sin {β}_{m ax}}{{n}_{1}} ) \qquad ( 2 )$$

For example, even if collection angle β is 90°, βᵢₙ would be 42° if the passivating material is SiO₂ or a polymer of refraction index (n₁) of 1.5.

In each of the examples provided herein, each the shaped pillars have at least a portion of a sidewall surface that is facing towards the light receiving surface so as to be at an acute angle with respect to the light receiving top surface. In the example of FIG. 1, each side (right and left) of each pillar has two of such surfaces. For instance, the right side of each pillar includes a shallow acute surface 131 such as that on the sidewall of pillar 111A, which is at an angle (90-α₂). Likewise, the right side of each pillar includes an acute surface 132 such as that on the side wall of the pillar 111B. The cell 100 is symmetric such that the left side wall is similarly structured for each pillar 110.

The shaped trenches 111 are shaped in such a way that the first reflection of the solar ray provides a further horizontal vector to the reflection so as to encourage multiple opportunities for the solar ray to be absorbed into a pillar for possible conversion into an electron-hole pair. Furthermore, each of the shaped trenches are structured such that upon some number of reflections, the solar ray is actually directed upwards. For instance, solar ray 141 of FIG. 1A is initially exactly vertical, but on encountering shallow acute surface 131 at the bottom of the trench 121B, the solar ray 141 is directed back upwards. A “shallow acute” angle means that the angle is greater than 15 degrees but less than a 40 degree angle with respect to the light receiving top surface 105. Thus, a vertical solar ray, when reflected of such a surface will be redirected upwards but with a strong horizontal component, thereby potentially allowing further reflections on the side walls and the way back up through the trench.

The solar ray 142, on the other hand, has a finite intake angle and first reflects off of a top portion 132 of the sidewall of the pillar 111B in FIG. 1A. Since the top portion 132 is at sharp acute angle (90-α₂) with respect to the lighting receiving surface, the reflected light ray continues a generally downward trajectory, but with a stronger horizontal vector, thereby encouraging multiple reflections, each representing an opportunity to enter into a pillar to perhaps cause generation of an electron-hole pair at or near one of the two photovoltaic junctions formed by the pillar. For instance, in the example of ray 142, a portion 142A is shown entering pillar 111C, while the remainder 142B continues on. After the fifth reflection of at least a portion solar ray 142, the solar ray is redirected upwards. In this description and in the claims, a “sharp acute” angle is an angle between 50 and 80 degrees with respect to the light receiving top surface 105.

Once the rays hit the solar cell, there are several different trajectories that a ray can follow. The ray can be trapped inside the shaped trench making several reflections with the sidewalls of the trench as shown in FIG. 1. For instance, the portion 142A of the ray is shown entering the pillar 111C in a rightward direction. A further reflected portion 142AA is shown reflecting back leftward to again experience two photovoltaic junctions within the pillar 111C. A further portion 142AB did not reflect, but enters a neighboring trench 121D at approximately the same angle as the solar ray was incident on the left sidewall of the pillar 111C.

FIG. 1B shows several alternative trajectories for solar rays. For instance, light ray 151 is shown entering the pillar 111A, and reflecting once of the right side of the pillar 111A. The light ray 152 is shown incident on the sharp acute surface 132. A portion 152A reflects back into the trench 122C, and enters the left sidewall of pillar 111C. A portion 152AA of that is reflected at the right sidewall of the pillar 111C back into the pillar 111C, and a portion 152AB continues into the next trench 122D and so on. Another portion 152B enters the top of the pillar 111B, internally reflects a few times, and then enters into the next trench 122B. Each time a solar ray is incident on a pillar surface from a trench, a portion of the solar ray will reflect back into the trench and a portion will be taken into the pillar. Each time a solar ray is incident on a sidewall of a pillar from within the pillar, a portion of the solar ray will be reflected back into the pillar and a portion of the solar ray will enter the neighboring trench from the sidewall.

FIG. 2A illustrates a cross section of a second three dimensional solar cell 200 with several solar ray trajectories shown. FIG. 2B illustrates a cross section of the second three dimensional solar cell 200 with several solar ray trajectories shown. The three dimensional solar cell 200 of FIG. 2 is similar to that of the solar cell 100 of FIG. 1 in that it also has a semiconductor body 210 in which an array of pillars 211 are formed, which define trenches 221 into which a passivation material 203 is provided thereby forming a light receiving surface 205. However, the pillars 211 are shaped slightly differently than the pillars of the first design. Specifically, each sidewall of each pillar is entirely at an acute angle with respect to the light receiving surface.

Again, the solar ray may enter either the trench or the silicon pillar, exit from the other side of the trench or pillar, and continue doing so. The shaping of the silicon is important to fully achieve this, but there is significant leeway in this design. As the solar ray bounces back and forth in the trench, each time the solar ray reflects, the amplitude of the solar ray diminishes. Assuming negligible absorption due to material filling the trench (SiO2, polymer or any other low index suitable dielectric), the reflection coefficient at each reflection can be estimated using the well-known Fresnel's equations. These equations depend on the angle of incidence, indices of silicon and the trough material and polarization.

The coefficient for each reflection for TE and TM polarizations are Γᵢ^{TE}(θᵢ) and Γᵢ^{TM}(θᵢ) respectively. Here θᵢ, is the angle of incident at i^{th} reflection. After k reflections the fraction of the ray that reflects back will be the product of the reflection coefficient of each reflection which can be concisely written as

$${\prod }_{i}^{k} {Γ}_{i}^{TE} ( {θ}_{i} ) or {\prod }_{i}^{k} {Γ}_{i}^{TM} ( {θ}_{i} ) .$$

Since each one of these reflection coefficients is less than 1, their product will be much less than 1 after a certain number of reflections. This number is usually less than four and after at most four reflections, the solar ray amplitude becomes negligible. Therefore to trap and absorb all the incident radiation there should be at most four reflections within a trench. Furthermore not all the reflections should point down.

Some of the reflections can direct the rays upwards towards the top of the trench as long as the total touches on the trench walls are four or more as indicated in FIG. 2. This assures that even if a solar ray goes back to air, the solar ray amplitude is so low that this back reflection is negligible for all practical purposes. For instance, ray 251 is directed upwards after 3 reflections, and ray 252 after 2 reflections. Accordingly, the trench need not be deep. Depths at the order of 10 micron or less may be acceptable.

Rays entering silicon pillars at each reflection will exit from the other side at the same angle after some absorption and back reflection into the silicon pillar. Therefore, after two reflections, the reduction in the solar ray amplitude for such a solar ray will be more than the reduction of a given solar ray that stays in the trench. Therefore if a solar ray goes through two trenches, its amplitude will be become negligible. The angle of the solar ray in the next trench will be the same as the angle of the ray in the first trench as shown in FIG. 2. It will only be directed down a slight amount. The angle the solar ray makes with respect to horizontal in a silicon pillar is significantly reduced due to higher index of the silicon. So once a solar ray makes it into a pillar, the solar ray will bounce back and forth within a short vertical distance until it is totally absorbed. Again, this principle illustrates that the silicon pillars need not to be very high.

All these discussions illustrate that a given ray that enters the surface of the solar cell does not likely reflect back. Instead, the ray bounces around inside the cell such that part of the spectrum that can be absorbed by silicon and converted into electricity will be absorbed and converted. Furthermore, a thin layer of silicon may be used to accomplish this. For instance, the depth of the trenches may be made shallow since some reflections occur on the way down, and some on the way up. Furthermore, in each of the designs of FIGS. 1 and 2, the average depth of each of the trenches is at least half that of the thickness of the semiconductor body between the top side of the semiconductor body and the bottom flat surface. However, the trench might be more than 30 percent or more than 40 percent of the thickness of the semiconductor body. While silicon has been described as the semiconductor material in which the depletion regions occur, other semiconductor materials may also suffice.

Electrical Design

The electrical design is important to efficiently collect electron-hole pairs generated in the cell. In this design, electrons are the minority carriers, although the principles described herein may also apply if holes arc the minority carriers. If the electrons reach the n+ silicon layer with minimal recombination, collection efficiency will be very high. Since most of the absorption takes place in the silicon pillars and since these pillars are quite narrow, the collection efficiency is significantly increased. Furthermore as mentioned above, the underlying silicon portion does not need to be thick. Hence, generated carriers can again be collected relatively efficiently. For instance, the pillars may be thin in the horizontal direction, with the average width at the midpoints being perhaps less than a half width, full width or twice the average width of the trenches at that midpoint.

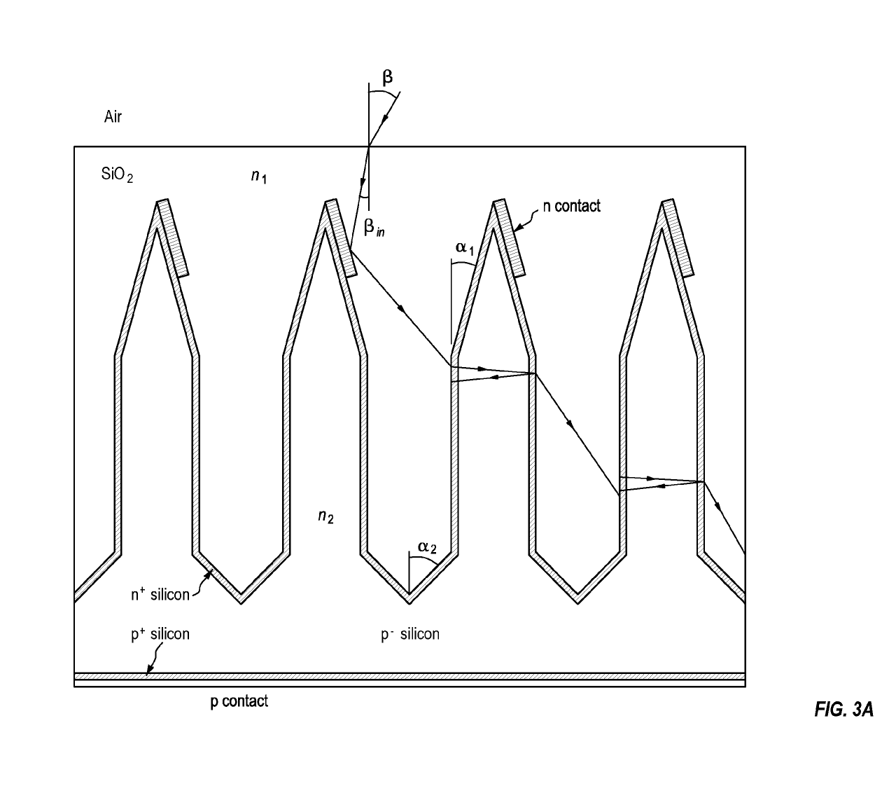

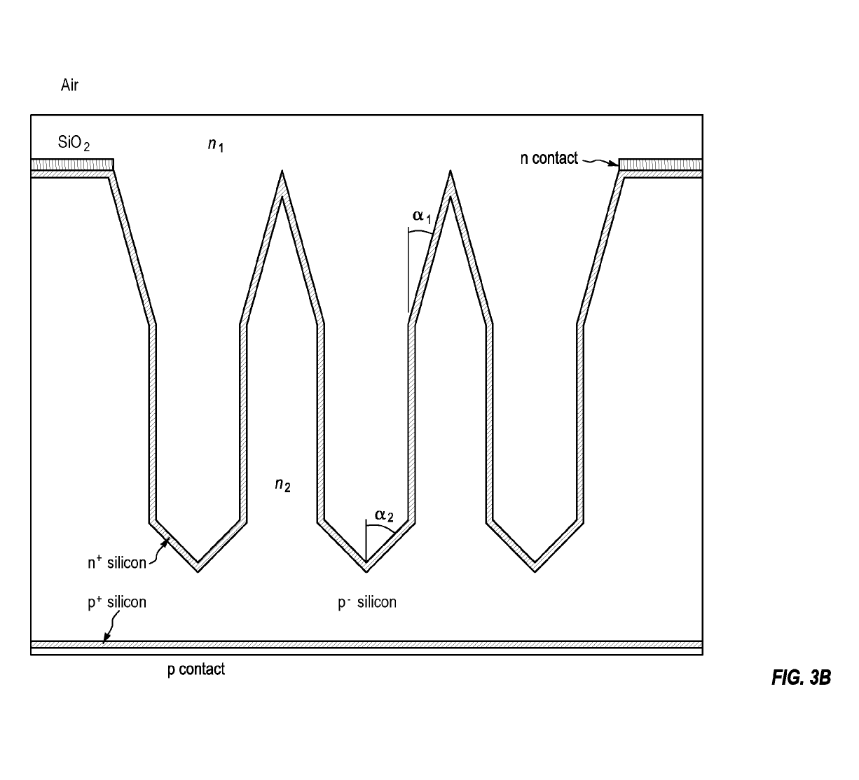

The p electrode (which is an ohmic contact) is on the bottom side of the wafer. The n electrode (which is also an ohmic contact) can be folded to the back side or can be made on the top surface using several different approaches. FIGS. 3A and 3B each illustrate a different such design. In the design in FIG. 3A, the n+ silicon layers are contacted by metal on one side on the top of the pillar. Such contacts can be formed by angle evaporation. All these contacts can instead be later combined on a flat part of the surface. The design of FIG. 3B includes some flat area of the n+silicon layers for the contact metal.

Fabrication Considerations

The shaping of the silicon in the described designs described can be done using dry and wet chemical etching. In dry etching, by adjusting the pressure of the plasma, some sidewall angle can be introduced. Even a sidewall angle such as 10-20° is enough to realize the type of design shown in FIG. 2. Chemical etches also can provide sloped sidewalls. These are usually along different crystal planes. By choosing the orientation of the wafer and appropriate chemical etches, sidewall from vertical to highly tilted can be obtained. Another approach to adjust the angle of the sidewall is to use a dynamic masking scheme. In this scheme the etchant used to etch silicon also etches the mask material. As a result, the mask opening constantly changes during etching. Hence a lateral etch also takes place in addition to vertical etch. Hence a sloped sidewall profile is obtained. Profiles from near vertical to long tapers are possible by adjusting the etch rate of the silicon and mask material.

After an initial masking, the silicon is shaped by etching. This is followed by n+ diffusion and surface passivation. After that, the contact openings and metallization top surface are filled either by flowable oxide or a polymer. Finally, the p contact is deposited on the bottom side of the solar cell, thereby completing fabrication. These steps are compatible with regular solar cell fabrication. Only the surface texturing and anti-reflection coating steps are replaced by the initial shaped etching of silicon.

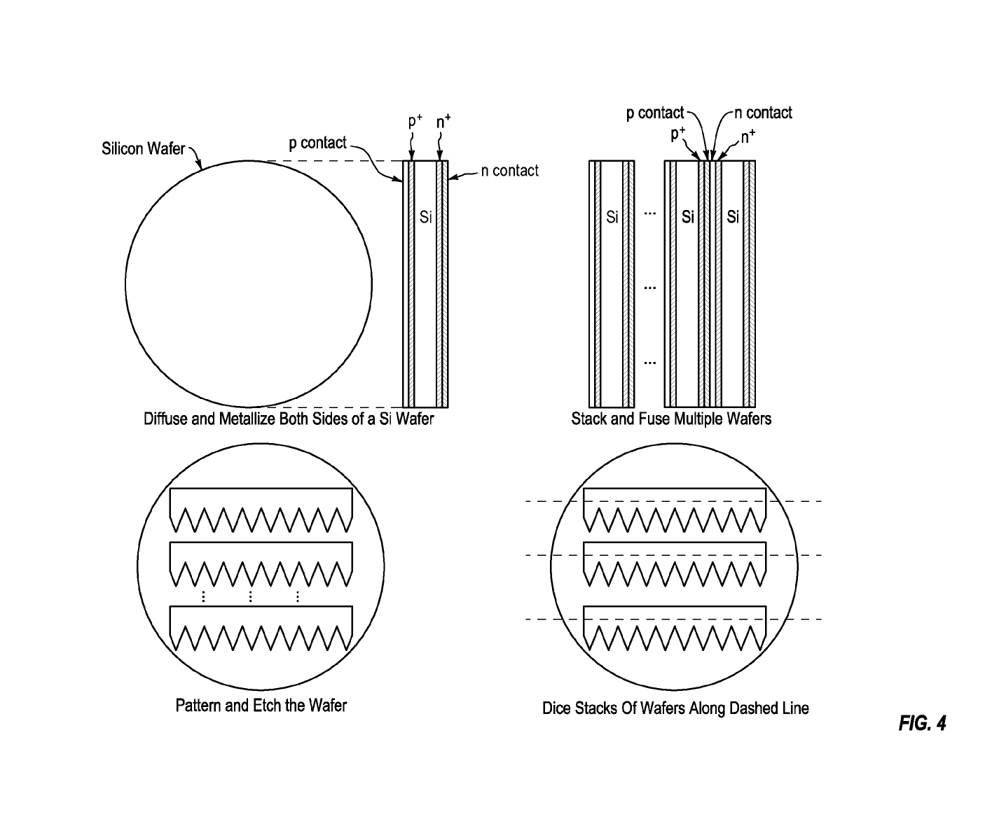

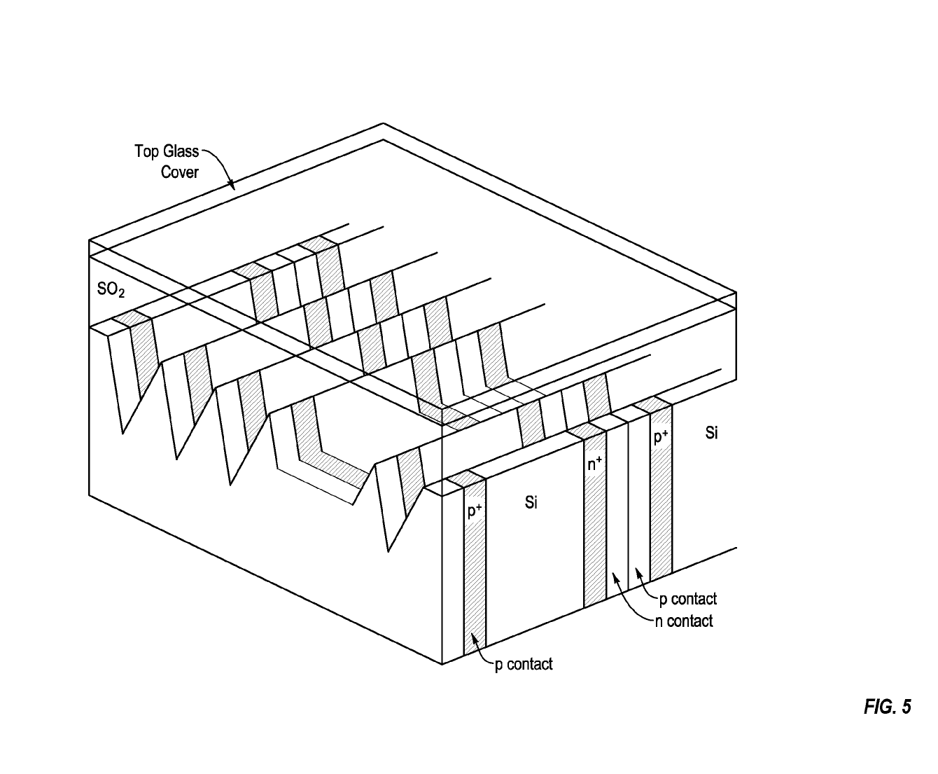

FIG. 4 illustrates fabrication steps for an alternate way of making wide angle solar cells as follows. In accordance with FIG. 4, fabrication starts by n+ doping one side of a whole silicon wafer and p+ doping the other side of the wafer. This is followed by depositing contact metals and sintering the contact on each side of the entire wafer. Next, the desired shapes of the solar cells are patterned on one side of the wafer. After that, metal contacts and silicon are etched. Multiple wafers produced this way are stacked and fused. Fusing is metal to metal and is straightforward. If desired, very thin solder material can coat the contacts reducing fusing temperature. This step connects individual solar cells on each wafer in series. After a certain number of such stacking, resulting thick wafers are sliced into long strips of solar cells. Later these strips are covered by SiO₂ or polymer and assembled on a glass cover slide. The other side can also be encapsulated in SiO₂ or polymer resulting in the cell structure shown in FIG. 5.

The resulting cells are very similar to the cells introduced earlier in FIG. 1 and FIG. 2, except that the p-electrode and the n-electrode are in front of and behind the solar cells as opposed to on the bottom and the top of the solar cells. Furthermore the shaping of the silicon is done by masking and etching so any shape on a mask can be obtained. Therefore, the desired light trapping can be achieved to an excellent accuracy. Carrier collection can also be done very efficiently by using thin wafers. Stacking of such wafers does not require precisely alignment. The cell will work as efficiently even if the stacked cells move up and down or sideways with respect to each other. Another advantage here is to obtain a cell area larger than the area of the wafers used. To explain this, suppose that each cell is 20 microns thick and the wafer is 150 micron thick. Furthermore, suppose slices of the stacked up cells is 50 microns thick. In this case, stacking all the slices out of a single wafer will result in a cell area 3 times the area of the wafer. Hence silicon consumption and cost will be reduced a factor of three, which is significant.

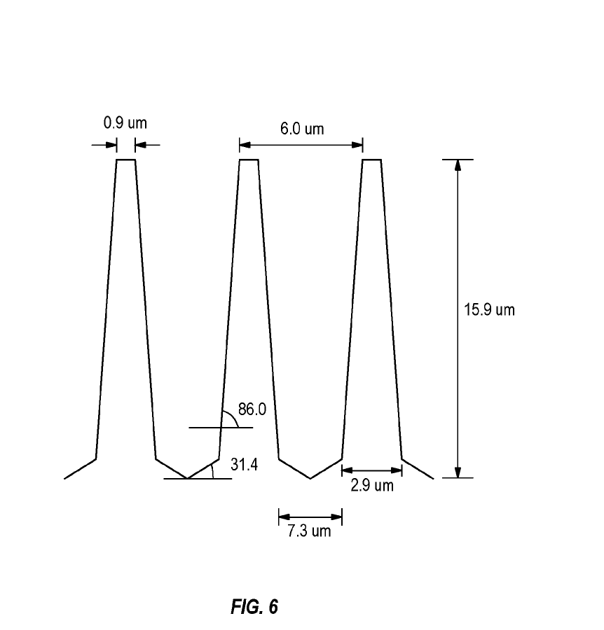

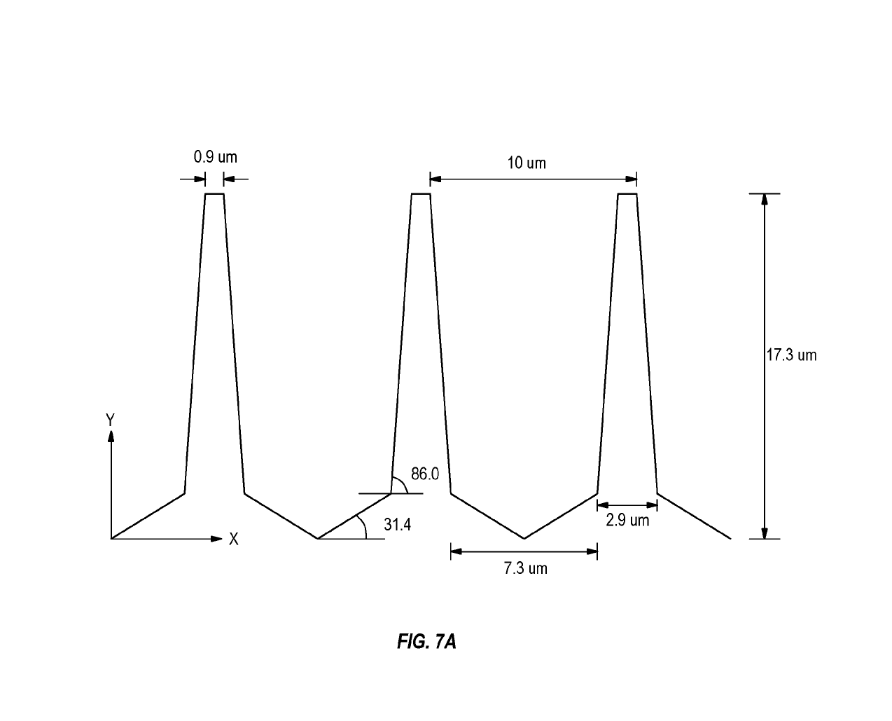

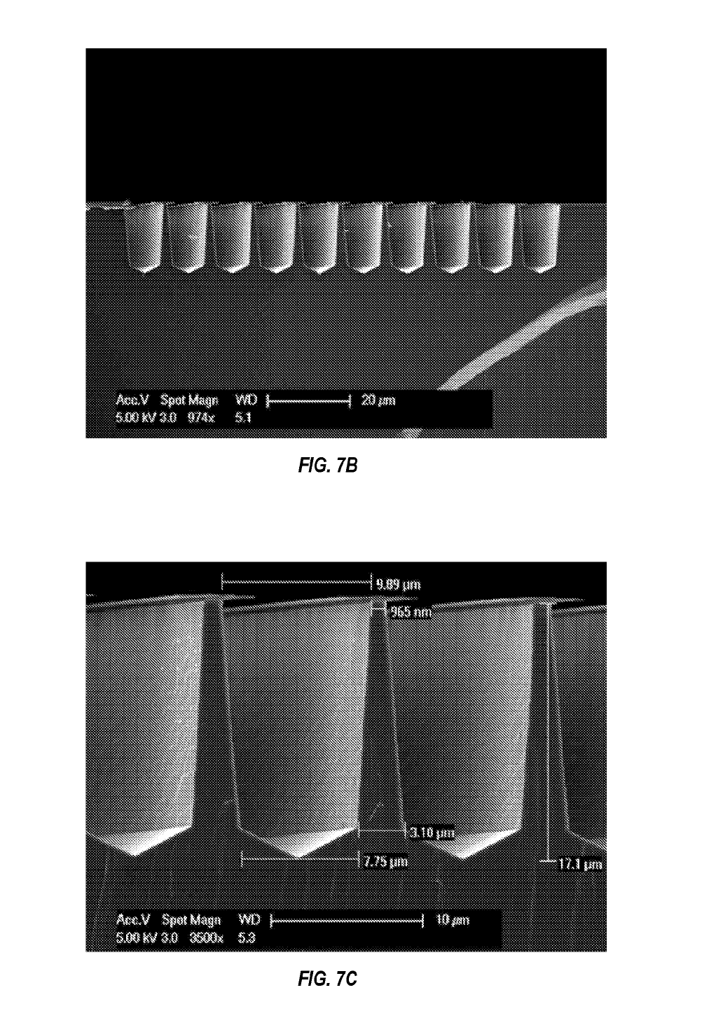

FIG. 6 illustrates an alternative cross section for the cells. FIG. 7A illustrates a second alternative cross section for the cells. FIG. 7B illustrates a microscopic cross sectional view of an actual trench array formed according to the approximate design of FIG. 7A. FIG. 7C illustrates a microscopic cross sectional view that represents a further zoomed in view of FIG. 7B, and with some measurements added.

Accordingly, a wide angle and efficient solar cell design has been described. The foregoing detailed description of various embodiments is provided by way of example and not limitation. Accordingly, the present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A three dimensional solar cell comprising:
a semiconductor body having a substantially flat bottom surface, and having a plurality of arrayed shaped trenches formed along a top side of the semiconductor body opposite the bottom surface, the semiconductor body forming a pillar between each neighboring shaped trench, such that the semiconductor body has a plurality of arrayed pillars extending toward the top side of the semiconductor body; and
a light collecting material filling the plurality of arrayed shaped trenches along the top side of the semiconductor body and forming a substantially flat light receiving top surface substantially parallel to the bottom surface of the semiconductor body, each of the plurality of arrayed pillars having sidewalls contacting the light collecting transparent material;
wherein each of a set of at least some of the plurality of trenches are structured such that for each of the pillars in the set of pillars, there exists at least one point on the substantially flat light receiving surface that if a light ray is incident on that point, the light ray, if remaining within the corresponding trench, as opposed to entering the semiconductor body, will be redirected upwards at least after a third reflection on neighboring pillars.

2. The solar cell in accordance with claim 1, wherein each of a set of at least some of the plurality of pillars have at least a portion of a sidewall surface that is facing towards the light receiving surface so as to be at an acute angle with respect to the light receiving top surface.

3. The solar cell in accordance with claim 1, wherein for a particular horizontal direction, an average thickness a midpoint of the set of pillars is horizontally thinner in that particular horizontal direction than an average thickness of at the midpoint of a corresponding inter-combed set of trenches of the plurality of trenches.

4. The solar cell in accordance with claim 1, wherein for a particular horizontal direction, an average thickness a midpoint of the set of pillars is horizontally thinner in that particular horizontal direction than half an average thickness of at the midpoint of a corresponding inter-combed set of trenches of the plurality of trenches.

5. The solar cell in accordance with claim 1, wherein for a particular horizontal direction, an average thickness a midpoint of the set of pillars is horizontally thinner in that particular horizontal direction than twice an average thickness of at the midpoint of a corresponding inter-combed set of trenches of the plurality of trenches.

6. The solar cell in accordance with claim 1, wherein an average depth of each of the plurality of trenches in the vertical direction perpendicular to the light receiving top surface is at least half that of the thickness of the semiconductor body between the top side of the semiconductor body and the bottom flat surface.

7. The solar cell in accordance with claim 1, wherein the average depth is less than ten microns.

8. The solar cell in accordance with claim 1, wherein an average depth of each of the plurality of trenches in the vertical direction perpendicular to the light receiving top surface is at least forty percent that of the thickness of the semiconductor body between the top side of the semiconductor body and the bottom flat surface.

9. The solar cell in accordance with claim 1, wherein an average depth of each of the plurality of trenches in the vertical direction perpendicular to the light receiving top surface is at least thirty percent that of the thickness of the semiconductor body between the top side of the semiconductor body and the bottom flat surface.

10. The solar cell in accordance with claim 1, wherein each of a second set of at least some of the plurality of trenches are structured such that for each of the pillars in the second set of pillars, there exists at least one point on the substantially flat light receiving surface that if a light ray is incident on that point, the light ray, if remaining within the corresponding trench, as opposed to entering the semiconductor body, will be redirected upwards at least after a third reflection on neighboring pillars.

11. The solar cell in accordance with claim 1, wherein each of a second set of at least some of the plurality of trenches are structured such that for each of the pillars in the second set of pillars, there exists at least one point on the substantially flat light receiving surface that if a light ray is incident on that point, the light ray, if remaining within the corresponding trench, as opposed to entering the semiconductor body, will be redirected upwards at least after a second reflection on neighboring pillars, and will have at least a fourth reflection on neighboring pillars.

12. The solar cell in accordance with claim 1, wherein along a particular horizontal direction, the set of pillars each have at least two photovoltaic junctions.

13. The solar cell in accordance with claim 1, wherein an electrical contact of a first polarity is coupled along the flat bottom surface of the semiconductor body.

14. The solar cell in accordance with claim 13, where for at least one of the plurality of the plurality of pillars, an electrical contact of a second polarity is positioned within a neighboring trench and coupled to the semiconductor body at a sidewall of the pillar.

15. The solar cell in accordance with claim 13, wherein an electrical contact of a second polarity is positioned on a flat portion of the top side of the semiconductor body.

16. The solar cell in accordance with claim 1, wherein an electrical contact of a first polarity is coupled along a front side of the semiconductor body.

17. The solar cell in accordance with claim 1, wherein an electrical contact of a second polarity is coupled along a back side of the semiconductor body.

18. A three dimensional solar cell comprising:
a semiconductor body having a substantially flat bottom surface, and having a plurality of arrayed shaped trenches formed along a top side of the semiconductor body opposite the bottom surface, the semiconductor body forming a pillar between each neighboring shaped trench, such that the semiconductor body has a plurality of arrayed pillars extending toward the top side of the semiconductor body; and
a light collecting material filling the plurality of arrayed shaped trenches along the top side of the semiconductor body and forming a substantially flat light receiving top surface substantially parallel to the bottom surface of the semiconductor body, each of the plurality of arrayed pillars having sidewalls contacting the light collecting transparent material;
wherein each of a set of at least some of the plurality of pillars have at least a portion of a sidewall surface that is facing towards the light receiving surface so as to be at an acute angle with respect to the light receiving top surface.

19. The solar cell in accordance with claim 18, wherein for at least one of the plurality of pillars, the sidewall surface comprises a top portion that has an acute angle with respect to the light receiving top surface.

20. The solar cell in accordance with claim 18, wherein for at least one of the plurality of pillars, the sidewall surface is entirely at an acute angle with respect to the light receiving top surface.
